(19) United States
(12) Patent Application Publication
(10) Pub. No.: US 2026/0351525 A1
(43) Pub. Date: Nov. 5, 2026

(54) PLASMA PROCESSING APPARATUS AND PLASMA PROCESSING METHOD

(71) Applicant: Tokyo Electron Limited, Tokyo (JP)

(72) Inventor: Masahito YAMAGUCHI, Miyagi (JP)

(73) Assignee: Tokyo Electron Limited, Tokyo (JP)

(21) Appl. No.: 19/726,907

(22) Filed: Jul. 1, 2026

Related U.S. Application Data
(63) Continuation of application No. PCT/JP2024/040504, filed on Nov. 14, 2024.

(30) Foreign Application Priority Data
Jan. 9, 2024 (JP) 2024-001278

(51) Int. Cl. H01J 37/32; H10P 50/28

(52) U.S. Cl. CPC H01J 37/32449; H10P 50/283; H01J 2237/334

(57) ABSTRACT

A plasma processing apparatus includes a chamber; a substrate support in the chamber; a first gas guide structure to supply a first processing gas into the chamber; a second gas guide structure to supply a second processing gas into the chamber; and controller circuitry configured to perform control operations including (a) providing, on the substrate support, a substrate including a silicon-containing layer, (b) generating a plasma from the first processing gas supplied from the first gas guide structure into the chamber and forming a layer on a bevel of the substrate, and (c) generating a plasma from the second processing gas supplied from the second gas guide structure into the chamber and etching the silicon-containing layer.

### CROSS-REFERENCE TO RELATED APPLICATIONS

This application is a bypass continuation application of International Application No. PCT/JP2024/040504 having an international filing date of Nov. 14, 2024 and designating the United States, the International Application being based upon and claiming the benefit of priority from Japanese Patent Application No. 2024-001278, filed on Jan. 9, 2024, the entire contents of each of which are incorporated herein by reference.

### BACKGROUND

### Field

Exemplary embodiments of the present disclosure relate to a plasma processing apparatus and a plasma processing method.

### Description of Related Art

JP 2013-115269 A describes a technique for removing deposits on an edge of a wafer.

### SUMMARY

In one exemplary embodiment of the present disclosure, a plasma processing apparatus includes a chamber; a substrate support in the chamber; a first gas guide structure to supply a first processing gas into the chamber; a second gas guide structure to supply a second processing gas into the chamber; and controller circuitry configured to perform control operations including (a) providing, on the substrate support, a substrate including a silicon-containing layer, (b) generating a plasma from the first processing gas supplied from the first gas guide structure into the chamber and forming a layer on a bevel of the substrate, and (c) generating a plasma from the second processing gas supplied from the second gas guide structure into the chamber and etching the silicon-containing layer.

### BRIEF DESCRIPTION OF DRAWINGS

The scope of the present disclosure is best understood from the following detailed description of exemplary embodiments when read in conjunction with the accompanying drawings.

FIG. 1 is a diagram of a plasma processing system, illustrating an example structure.

FIG. 2 is a diagram of a capacitively coupled plasma processing apparatus, illustrating an example structure.

FIG. 3 is a diagram of an example first gas guide unit and an example second gas guide unit.

FIG. 4 is a diagram of the bottom surface of a showerhead 13 in FIG. 3.

FIG. 5 is a flowchart of an example of a method MT.

FIG. 6 is a diagram of a substrate W showing an example cross-sectional structure.

FIG. 7 is a diagram of an example bevel of the substrate W before the processing in step ST12.

FIG. 8 is a diagram of an example bevel of the substrate W after the processing in step ST12.

FIG. 9 is a diagram of the substrate W during the processing in step ST13, showing an example cross-sectional structure.

FIG. 10 is a diagram of an example bevel of the substrate W after the processing in step ST13.

FIG. 11 is a flowchart of another example of the method MT.

FIG. 12 is a flowchart of another example of the method MT.

### DETAILED DESCRIPTION

One or more embodiments of the present disclosure will be described below.

In one exemplary embodiment, a plasma processing apparatus includes a chamber a substrate support in the chamber, a first gas guide unit that supplies a first processing gas into the chamber, a second gas guide unit that supplies a second processing gas into the chamber, and a controller. The controller performs control operations including (a) providing, on the substrate support, a substrate including a silicon-containing film, (b) generating a plasma from the first processing gas supplied from the first gas guide unit into the chamber and forming a film on a bevel of the substrate, and (c) generating a plasma from the second processing gas supplied from the second gas guide unit into the chamber and etching the silicon-containing film (hereinafter “film” means the same as “layer”).

In one exemplary embodiment, the first processing gas includes a CF-based gas.

In one exemplary embodiment, the CF-based gas includes at least one gas selected from the group consisting of a C₄F₈ gas, a C₄F₆ gas, a C₃F₈ gas, a C₃F₆ gas, and a CF₄ gas.

In one exemplary embodiment, the second processing gas includes a CHF-based gas.

In one exemplary embodiment, the CHF-based gas includes at least one gas selected from the group consisting of a C₄H₂F₆ gas, a C₃H₂F₄ gas, and a CH₂F₂ gas.

In one exemplary embodiment, the first gas guide unit (herein “first gas guide unit” means the same as “first gas guide structure”) is located radially outward from the second gas guide unit (herein “second gas guide unit” means the same as “second gas guide structure”).

In one exemplary embodiment, the first gas guide unit surrounds the second gas guide unit.

In one exemplary embodiment, the plasma processing apparatus further includes showerhead facing the substrate support and including a plurality of gas supply holes over an area extending from a central portion to an outer peripheral portion of the showerhead. The first gas guide unit is located in the outer peripheral portion of the showerhead. The second gas guide unit is located in the central portion of the showerhead.

In one exemplary embodiment, the plasma processing apparatus further includes showerhead facing the substrate support and including a plurality of gas supply holes. The first gas guide unit is located in a sidewall of the chamber. The second gas guide unit is located in the showerhead.

In one exemplary embodiment, after (b) is performed, (c) is performed.

In one exemplary embodiment, (b) and (c) are performed simultaneously.

In one exemplary embodiment, after (b) and (c) are performed simultaneously, (c) i s further performed.

In one exemplary embodiment, the second processing gas further includes a hydrogen fluoride gas.

In one exemplary embodiment, the second processing gas further includes at least one gas selected from the group consisting of a phosphorus-containing gas, a gas containing a halogen other than fluorine, a metal-containing gas, an oxygen-containing gas, and an inert gas.

In one exemplary embodiment, a plasma processing method includes (a) providing a substrate including a silicon-containing film on a substrate support in a chamber, (b) generating a plasma from a first processing gas supplied from a first gas guide unit into the chamber and forming a film on a bevel of the substrate, and (c) generating a plasma from a second processing gas supplied from a second gas guide unit into the chamber and etching the silicon-containing film.

In one exemplary embodiment, the first processing gas includes a CF-based gas.

In one exemplary embodiment, the second processing gas includes a CHF-based gas.

In one exemplary embodiment, after (b) is performed, (c) is performed.

In one exemplary embodiment, (b) and (c) are performed simultaneously.

In one exemplary embodiment, after (b) and (c) are performed simultaneously, (c) is further performed.

One or more embodiments of the present disclosure will be described below with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example Structure of Plasma Processing System

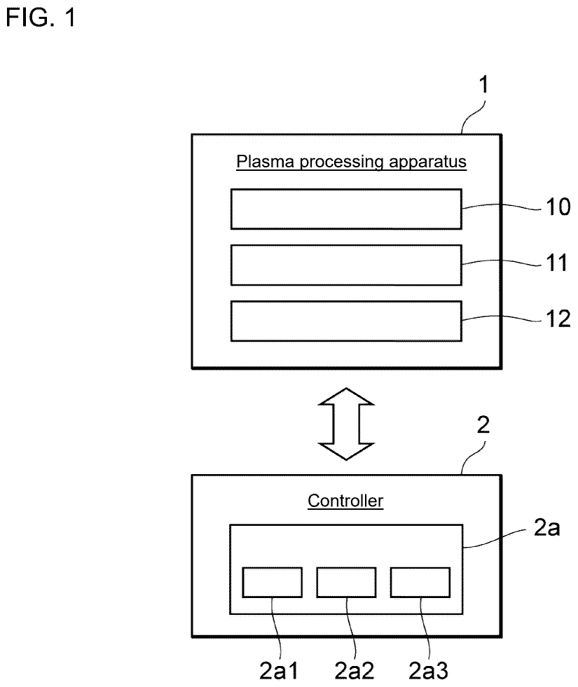

FIG. 1 is a diagram of a plasma processing system, illustrating an example structure. In one embodiment, the plasma processing system includes a plasma processing apparatus 1 and a controller 2 (herein “controller” means the same as “controller circuitry”). The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one processing gas into the plasma processing space and at least one gas outlet for exhausting the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates a plasma from at least one processing gas supplied into the plasma processing space. The plasma generated in the plasma processing space may be, for example, a capacitively coupled plasma (CCP), an inductively coupled plasma (ICP), an electron cyclotron resonance (ECR) plasma, a helicon wave plasma (HWP), or a surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may cause the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading programs from the storage 2a2 and executing the loaded programs. The programs may be prestored in the storage 2a2 or may be obtained through a medium as appropriate. The obtained programs are stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

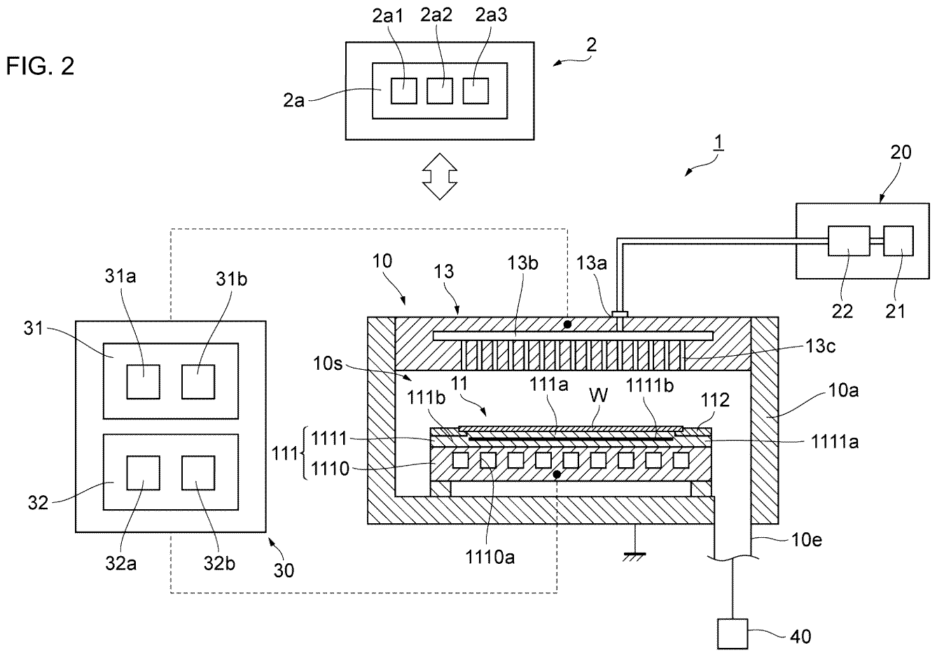

An example structure of a capacitively coupled plasma processing apparatus as an example of the plasma processing apparatus 1 will be described below. FIG. 2 is a diagram of the capacitively coupled plasma processing apparatus, illustrating an example structure.

The capacitively coupled plasma processing apparatus 1 includes the plasma processing chamber 10, the gas supply 20, a power supply 30, and the exhaust system 40. The plasma processing apparatus 1 further includes the substrate support 11 and a gas guide unit. The gas guide unit allows at least one processing gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one processing gas from the gas supply 20 into the plasma processing space 10s. The showerhead 13 includes at least one gas inlet 13a, at least one gas-diffusion compartment 13b, and multiple gas guides 13c. The processing gas supplied to the gas inlet 13a passes through the gas-diffusion compartment 13b and is introduced into the plasma processing space 10s through the multiple gas guides 13c. The showerhead 13 further includes at least one upper electrode. In addition to the showerhead 13, the gas guide unit may include one or more side gas injectors (SGIs) installed in one or more openings in the sidewall 10a.

The gas supply 20 may include at least one gas source 21 and at least one flow controller 22. In one embodiment, the gas supply 20 supplies at least one processing gas from each gas source 21 to the showerhead 13 through the corresponding flow controller 22. The flow controller 22 may be, for example, a mass flow controller or a pressure-based flow controller. The gas supply 20 may further include at least one flow rate modulator that causes at least one processing gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates a plasma from at least one processing gas supplied into the plasma processing space 10s. The RF power supply 31 may thus function as at least a part of the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode. In one embodiment, the second DC generator 32b is coupled to at least one upper electrode to generate a second DC signal. The generated second DC signal is applied to at least one upper electrode.

In various embodiments, the first DC signal and the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

### Example of Gas Guide Unit

In one embodiment, the gas guide unit in the plasma processing apparatus 1 includes a first gas guide unit and a second gas guide unit. The first gas guide unit supplies a first processing gas into the chamber 10. The second gas guide unit supplies a second processing gas into the chamber 10. In one embodiment, the first gas guide unit is located radially outward from the second gas guide unit. In one embodiment, the first gas guide unit surrounds the second gas guide unit.

In one embodiment, both the first gas guide unit and the second gas guide unit are located in the showerhead 13. In one embodiment, the first gas guide unit may be located in an outer peripheral portion of the showerhead 13, and the second gas guide unit may be located in a central portion of the showerhead 13.

In one embodiment, the second gas guide unit is located in the showerhead 13, and the first gas guide unit is at a position other than in the showerhead 13. For example, the first gas guide unit may be one or more SGIs installed in one or more openings in the sidewall 10a.

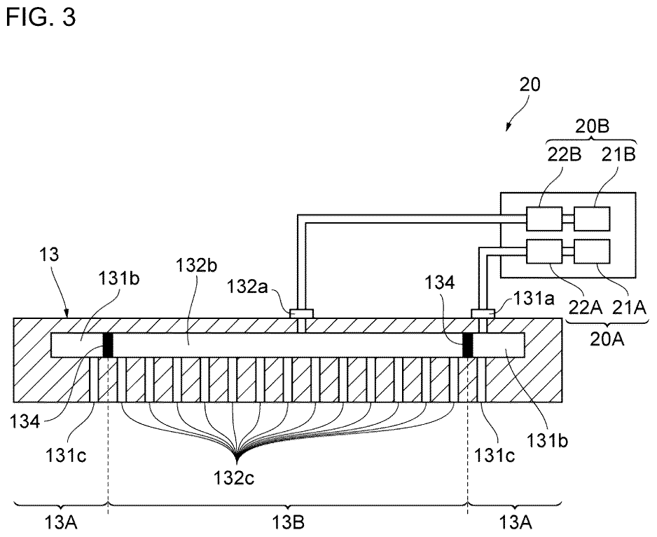

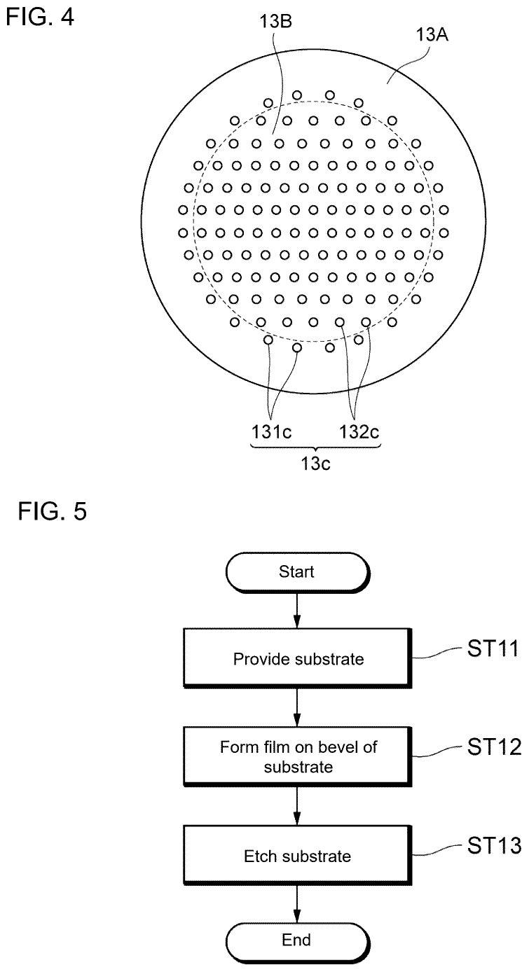

FIG. 3 is a diagram of an example first gas guide unit and an example second gas guide unit. FIG. 4 is a diagram of the bottom surface of the showerhead 13 in FIG. 3. As shown in FIGS. 3 and 4, the showerhead 13 includes an outer peripheral portion 13A and a central portion 13B. The central portion 13B extends radially outward from the center of the showerhead 13. The central portion 13B may include a portion facing the central portion 111a (refer to FIG. 2) of the substrate support 11. The outer peripheral portion 13A extends radially outward from the central portion 13B to surround the central portion 13B. The outer peripheral portion 13A may include a portion facing the ring assembly 112 or an outer edge of the substrate W placed on the substrate support 11, or both (refer to FIG. 2).

In one embodiment, the first gas guide unit may be located in the outer peripheral portion 13A of the showerhead 13, and the second gas guide unit may be located in the central portion 13B of the showerhead 13 as shown in FIGS. 3 and 4. The showerhead 13 includes, as the first gas guide unit, a first gas inlet 131a, a first gas-diffusion compartment 131b, and multiple first gas guides 131c in the outer peripheral portion 13A. The showerhead 13 includes, as the second gas guide unit, a second gas inlet 132a, a second gas-diffusion compartment 132b, and multiple second gas guides 132c in the central portion 13B. The first gas-diffusion compartment 131b and the second gas-diffusion compartment 132b are separate from each other with an annular partition 134 between them. In one example, the annular partition 134 is an O-ring.

In one embodiment, the gas supply 20 includes a first gas supply 20A that supplies the first processing gas, and a second gas supply 20B that supplies the second processing gas. In one embodiment, the gas supply 20 may further include at least one flow rate modulator that causes the first processing gas or the second processing gas, or both to be supplied at modulated flow rates or in a pulsed manner.

In one embodiment, the first gas supply 20A includes one or more gas sources 21A each including a gas included in the first processing gas and the corresponding one or more flow controllers 22A. The first gas supply 20A is connected to the first gas inlet 131a in the first gas guide unit. The first processing gas supplied from the first gas supply 20A to the first gas inlet 131a passes through the first gas-diffusion compartment 131b and is introduced into the plasma processing space 10s through the first gas guides 131c. As shown in FIG. 4, the first gas guides 131c in the outer peripheral portion 13A of the showerhead 13 are located radially outward from the second gas guides 132c in the central portion 13B. The first processing gas is thus introduced into the plasma processing space 10s at positions radially outward from the positions at which the second processing gas is introduced. In one embodiment, the first processing gas is selectively supplied to the outer edge (bevel) of the substrate W placed on the substrate support 11.

In one embodiment, the second gas supply 20B includes one or more gas sources 21B each including a gas included in the second processing gas and the corresponding one or more flow controllers 22B. The second gas supply 20B is connected to the second gas inlet 132a in the second gas guide unit. The second processing gas supplied from the second gas supply 20B to the second gas inlet 132a passes through the second gas-diffusion compartment 132b and is introduced into the plasma processing space 10s through the second gas guides 132c. As shown in FIG. 4, the second gas guides 132c in the central portion 13B of the showerhead 13 are located radially inward from the first gas guides 131c in the outer peripheral portion 13A. The second processing gas is thus introduced into the plasma processing space 10s at positions radially inward from the positions at which the first processing gas is introduced.

### Example of Plasma Processing Method

FIG. 5 is a flowchart of an example of a plasma processing method (hereafter also referred to as a method MT) according to one exemplary embodiment. As shown in FIG. 5, the method MT includes step ST11 of providing a substrate, step ST12 of forming a film on the bevel of the substrate, and step ST13 of etching the substrate. The processing in each step may be performed in the plasma processing apparatus 1 shown in FIGS. 1 to 3. The controller 2 causes the components of the plasma processing apparatus 1 to perform the method MT on the substrate W in the example described below.

### Step ST11: Providing Substrate

In step ST11, the substrate W is provided into the plasma processing chamber 10 (hereafter also referred to as the chamber 10). The substrate W is loaded into the chamber 10 with a transfer arm, placed onto the substrate support 11 with a lifter, and clamped on the substrate support 11 as shown in FIG. 2.

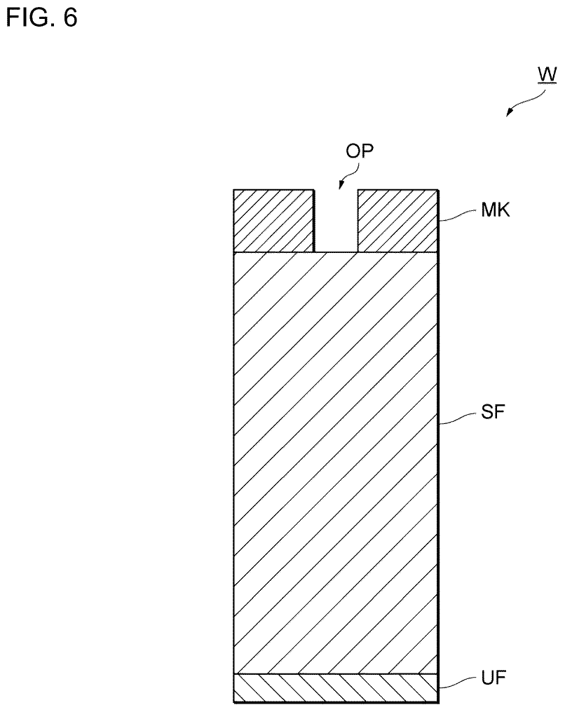

FIG. 6 is a diagram of the substrate W showing an example cross-sectional structure. The substrate W includes a silicon-containing film SF and a mask MK on the silicon-containing film SF. The silicon-containing film SF may be located on an underlying film UF. The substrate W may be used for manufacturing semiconductor devices. Examples of the semiconductor devices include a memory device such as a dynamic RAM (DRAM) or a three-dimensional NOT-AND (3D-NAND) flash memory, and a logic device.

The underlying film UF may be, for example, a silicon wafer or an organic film, a dielectric film, a metal film, or a semiconductor film on the silicon wafer. The underlying film UF may include multiple films stacked on one another.

The silicon-containing film SF is a target film for etching with the method MT. In one embodiment, the silicon-containing film SF may be a film stack including at least two different films selected from a silicon oxide film, a silicon nitride film, a silicon carbonitride film, a polycrystalline silicon film, and a carbon-containing silicon film. For example, the silicon-containing film SF may include silicon oxide films and silicon nitride films alternately stacked on one another. For example, the silicon-containing film SF may include silicon oxide films and polycrystalline silicon films alternately stacked on one another. For example, the silicon-containing film SF may be a film stack including a silicon nitride film, a silicon oxide film, and a polycrystalline silicon film. For example, the silicon-containing film SF may include a silicon oxide film and a silicon carbonitride film stacked on each other. For example, the silicon-containing film SF may be a film stack including a silicon oxide film, a silicon nitride film, and a silicon carbonitride film. In one embodiment, the silicon-containing film SF may be partially doped with an element such as phosphorus, boron, or nitrogen.

The mask MK may be formed from a material having a lower etching rate in a plasma generated in step ST13 than the material of the silicon-containing film SF. The mask MK may be a single layer mask including one film or a multilayer mask including two or more films.

In one embodiment, the mask MK includes a metal-containing film. In one embodiment, the metal-containing film contains at least one metal (hereafter also referred to as a metal M) selected from the group consisting of tungsten, molybdenum, ruthenium, and titanium. In one embodiment, the metal-containing film contains the metal M and at least one element selected from the group consisting of silicon, carbon, nitrogen, oxygen, boron, hydrogen, and phosphorus. For example, the metal-containing film may contain at least one selected from the group consisting of tungsten carbide (WC), tungsten silicide (WSi), tungsten silicon nitride (WSiN), and tungsten silicon carbide (WSiC).

In one embodiment, the mask MK includes a carbon-containing film. In one embodiment, the carbon-containing film is an amorphous carbon layer (ACL), a spin-on-carbon (SOC) film, or a photoresist film. The ACL may be doped with an element such as boron. Examples of the ACL include a boron-containing ACL (B-doped ACL), an arsenic-containing ACL (As-doped ACL), a tungsten-containing ACL (W-doped ACL), and a xenon-containing ACL (Xe-doped ACL).

As shown in FIG. 6, the mask MK defines at least one opening OP on the silicon-containing film SF. The opening OP is a space on the silicon-containing film SF, surrounded by a sidewall of the mask MK. In other words, the upper surface of the silicon-containing film SF includes a portion covered with the mask MK and a portion exposed through the bottom of the opening OP.

The opening OP may have any feature in a plan view of the substrate W, or in other words, when the substrate W is viewed from the top to the bottom in FIG. 6. The opening feature may be, for example, a circle, an oval, a rectangle, a line, or a combination of one or more of these features. The mask MK may include multiple sidewalls, which may define multiple openings OP. The mask MK may thus have an opening pattern. For example, the mask MK may have the multiple openings OP that are slits as viewed in plan and arranged at intervals and may thus have a pattern of lines and spaces. In another example, the mask MK may have the multiple openings OP that are circular and arranged in dots and may thus have a patterned array.

The underlying film UF, the silicon-containing film SF, and the mask MK may each be formed with any method. For example, the underlying film UF, the silicon-containing film SF, and the mask MK may each be formed by chemical vapor deposition (CVD), atomic layer deposition (ALD), physical vapor deposition (PVD), spin coating, or other methods. The mask MK may be formed by, for example, lithography. The opening OP in the mask MK may be formed by etching the mask MK. The underlying film UF, the silicon-containing film SF, and the mask MK may each be a flat film or an uneven film. The substrate W may further include another film under the underlying film UF. In this structure, the silicon-containing film SF and the underlying film UF may have recesses with features corresponding to the opening OP, and may be used as a mask for etching the other film.

The process of forming the underlying film UF, the silicon-containing film SF, and the mask MK in the substrate W may be at least partially performed in the chamber 10 as part of step ST11. When the opening OP in the mask MK is formed by etching, the processing in step ST12 may be performed before etching in step ST11. In other words, after the film is formed on the bevel of the substrate W, the opening OP in the mask MK may be etched. In one embodiment, all or a part of the substrate W may be formed in an apparatus or a chamber external to the plasma processing apparatus 1 and then provided into the chamber 10.

In one embodiment, after the substrate W is provided on the central portion 111a of the substrate support 11, the temperature of the substrate support 11 is controlled to be a set temperature by the temperature controller. In one example, controlling the temperature of the substrate support 11 to be the set temperature includes causing the temperature of the heat transfer fluid flowing through the channel 1110a and the temperature of the heater to be the respective set temperatures, or to be temperatures different from the respective set temperatures. The heat transfer fluid may start to flow through the channel 1110a before, after, or at the same time as the substrate W is placed onto the substrate support 11. The temperature of the substrate support 11 may be controlled to be the set temperature before step ST11. In other words, the substrate W may be provided on the substrate support 11 after the temperature of the substrate support 11 is controlled to be the set temperature.

In one embodiment, the temperature of the substrate W may be, in place of the temperature of the substrate support 11, controlled to be the set temperature. Controlling the temperature of the substrate W to be the set temperature includes causing at least one of the temperature of the substrate support 11, the temperature of the heat transfer fluid flowing through the channel 1110a, or the temperature of the heater to be the set temperature, or to be a temperature different from the set temperature.

### Step ST12: Forming Film on Bevel of Substrate

In step ST12, a film is formed on the bevel of the substrate W using a plasma generated from the first processing gas. Step ST12 includes supplying the first processing gas into the chamber 10 and generating a plasma from the first processing gas.

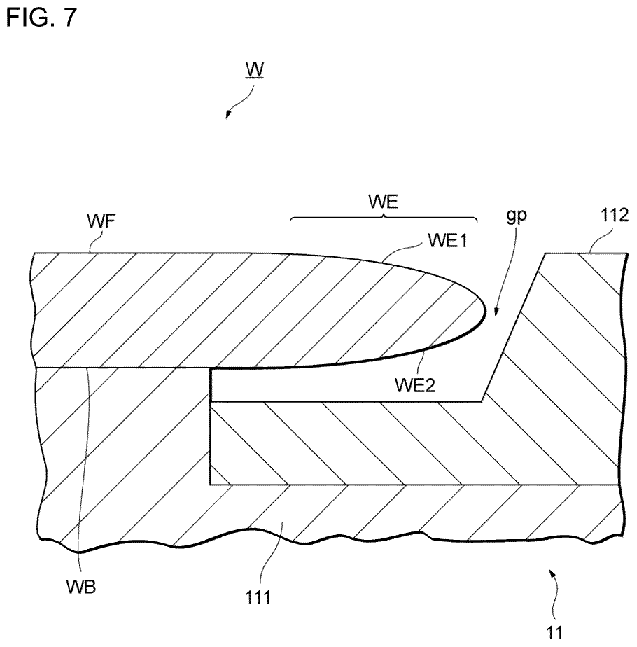

FIG. 7 is a diagram of an example bevel of the substrate W before the processing in step ST12. As shown in FIG. 7, the substrate W includes a main surface WF, a back surface WB, and a bevel WE. The main surface WF is a surface on which the silicon-containing film SF, the mask MK (refer to FIG. 6), or other films are formed. The back surface WB is opposite to the main surface WF. The bevel WE is continuous with the main surface WF and the back surface WB. The bevel WE defines the outer edge of the substrate W.

The bevel WE may have an end WE1 and an end WE2. The end WE1 is continuous with the main surface WF with a slope at an angle less than 90 degrees to the main surface WF in a cross-sectional view. The end WE2 is continuous with the back surface WB with a slope at an angle less than 90 degrees to the back surface WB. The ends WE1 and WE2 may be curved or tapered. The end WE1 may include one or more films (e.g., at least one of the underlying film UF, the silicon-containing film SF, or the mask MK) on the silicon wafer. In other words, the silicon wafer may not be exposed on the end WE1. The end WE2 may include no film on the silicon wafer. In other words, the silicon wafer may be exposed on the end WE2. In one embodiment, a clearance gp is left between the bevel WE of the substrate W and the ring assembly 112 with the substrate W placed on the body 111 of the substrate support 11.

In step ST12, the first processing gas is supplied from the first gas guide unit into the chamber 10. More specifically, the first processing gas is supplied from the first gas supply 20A to the first gas inlet 131a (refer to FIG. 3). The first processing gas passes through the first gas-diffusion compartment 131b and is introduced into the plasma processing space 10s through the first gas guides 131c. The first gas guides 131c are located in the outer peripheral portion 13A of the showerhead 13 (refer to FIGS. 3 and 4). The first processing gas is supplied to at least the bevel WE of the substrate W.

The first processing gas forms a film on the bevel WE of the substrate W. In one embodiment, the first processing gas is a carbon-containing gas free of hydrogen. In one embodiment, the first processing gas is a CF-based gas (fluorocarbon gas). The CF-based gas may be at least one selected from the group consisting of a CF₄ gas, a C₂F₂ gas, a C₂F₄ gas, a C₃F₆ gas, a C₃F₈ gas, a C₄F₆ gas, a C₄F₈ gas, and a C₅F₈ gas.

In step ST12, a plasma is generated from the first processing gas in the chamber 10. For example, a source RF signal is provided to the lower electrode in the substrate support 11 or the upper electrode in the showerhead 13, or both. In this case, a bias signal may or may not be provided to the lower electrode in the substrate support 11. In response to an RF electric field being generated between the showerhead 13 and the substrate support 11, a plasma is generated from the first processing gas in the chamber 10. The first processing gas may be supplied more to the bevel WE of the substrate W than to the central portion of the substrate W, as described above. The plasma generated from the first processing gas may have a greater density above the bevel WE of the substrate W than above the central portion of the substrate W. A portion of the active species dissociated from the first processing gas is deposited on the bevel WE of the substrate W, forming a film on the bevel WE. When the clearance gp is left between the bevel WE of the substrate W and the ring assembly 112, the portion of the active species dissociated from the first processing gas may reach the back surface WB of the substrate W through the clearance gp, forming a film on the back surface WB of the substrate W as shown in FIG. 7.

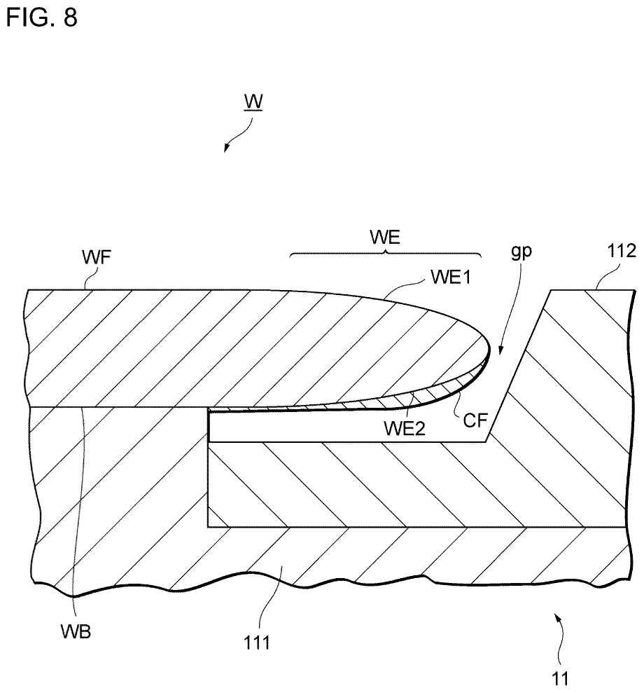

FIG. 8 is a diagram of an example bevel of the substrate W after the processing in step ST12. In the example shown in FIG. 8, the bevel WE includes a film CF on the end WE2 (back side). For the first processing gas being a carbon-containing gas, the film CF is a carbon-containing film. For the first processing gas being a CF-based gas, the film CF and the substrate W have higher adhesion between them. The film CF is thus less likely to separate from the substrate W during etching in step ST13. In one embodiment, the film CF may be formed on both the end WE1 (main side) and the end WE2 (back side) of the bevel WE. In one embodiment, the film CF may or may not be formed on a portion of the main surface WF of the substrate W.

### Step ST13: Etching Substrate

In step ST13, the substrate W is etched using a plasma generated from the second processing gas. Step ST13 includes supplying the second processing gas into the chamber 10 and generating a plasma from the second processing gas.

In step ST13, the second processing gas is supplied from the second gas guide unit into the chamber 10. More specifically, the second processing gas is supplied from the second gas supply 20B to the second gas inlet 132a (refer to FIG. 3). The second processing gas passes through the second gas-diffusion compartment 132b and is introduced into the plasma processing space 10s through the second gas guides 132c. The second gas guides 132c are located in the central portion 13B of the showerhead 13 (refer to FIGS. 3 and 4). The second processing gas is supplied to at least the central portion of the substrate W.

In one embodiment, the second processing gas includes a hydrogen fluoride (HF) gas. The HF gas may have the highest flow rate (partial pressure) among the second processing gas excluding an inert gas. In one example, the flow rate of the HF gas may be 50 vol % or more, 60 vol % or more, 70 vol % or more, 80 vol % or more, 90 vol % or more, or 95 vol % or more of the total flow rate of all components of the second processing gas (all components of the second processing gas excluding any inert gas included in the second processing gas; the same applies hereafter). The flow rate of the HF gas may be less than 100 vol %, 99.5 vol % or less, 98 vol % or less, or 96 vol % or less of the total flow rate of all components of the second processing gas. In one example, the flow rate of the HF gas is 70 to 96 vol % inclusive of the total flow rate of all components of the second processing gas.

In one embodiment, the second processing gas may further include a phosphorus-containing gas. The phosphorus-containing gas may be, for example, a phosphorus halide gas. The phosphorus halide gas may be at least one selected from the group consisting of a PF₃ gas, a PF₅ gas, a PCl₃ gas, a PCl₅ gas, a PClF₂ gas, a PCl₂F gas, and a PCl₂F₃ gas. In one example, the phosphorus halide gas is a PF₃ gas, a PF₅ gas, or a PCl₃ gas.

In one embodiment, the second processing gas may further include a carbon-containing gas. The carbon-containing gas may be, for example, a CF-based gas (fluorocarbon gas) or a CHF-based gas (hydrofluorocarbon gas), or both. In one example, the CF-based gas may be at least one selected from the group consisting of a CF₄ gas, a C₂F₂ gas, a C₂F₄ gas, a C₃F₆ gas, a C₃F₈ gas, a C₄F₆ gas, a C₄F₈ gas, and a C₅F₈ gas. In one example, the CHF-based gas may be at least one selected from the group consisting of a CHF₃ gas, a CH₂F₂ gas, a CH₃F gas, a C₂HF₅ gas, a C₂H₂F₄ gas, a C₂H₃F₃ gas, a C₂H₄F₂ gas, a C₃HF₇ gas, a C₃H₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F₁₀ gas, and a C₅H₃F₇ gas. The carbon-containing gas may have a linear chain structure with unsaturated bonds. The linear carbon-containing gas with unsaturated bonds may be, for example, at least one selected from the group consisting of a hexafluoropropene (C₃F₆) gas, an octafluoro-1-butene (C₄F₈) gas, an octafluoro-2-butene (C₄F₈) gas, a 1,3,3,3-tetrafluoropropene (C₃H₂F₄) gas, a trans-1,1,1,4,4,4-hexafluoro-2-butene (C₄H₂F₆) gas, a pentafluoroethyl trifluorovinyl ether (C₄F₈°) gas, a 1,2,2,2-tetrafluoroethane-1-one (CF₃COF) gas, a difluoroacetic acid fluoride (CHF₂COF) gas, and a carbonyl fluoride (COF₂) gas.

In one embodiment, the second processing gas may further include a metal-containing gas. The metal-containing gas contains at least one metal selected from the group consisting of tungsten, titanium, ruthenium, and molybdenum. In one embodiment, the metal-containing gas may further contain a halogen. The metal-containing gas may be, for example, a WF₂ gas, a WF₄ gas, a WF₅ gas, a WF₆ gas, a WCl₂ gas, a WCl₄ gas, a WCl₅ gas, a WCl₆ gas, a MoF₄ gas, a MoF₆ gas, a MoCl₆ gas, or a TiCl₄ gas. The flow rate of the metal-containing gas may be 5 vol % or less of the total flow rate of all components of the second processing gas.

In one embodiment, the second processing gas may further include a gas containing a halogen other than fluorine. The gas containing a halogen other than fluorine is, for example, at least one of a chlorine-containing gas, a bromine-containing gas, or an iodine-containing gas. In one example, the chlorine-containing gas is at least one gas selected from the group consisting of Cl₂, SiCl₂, SiCl₄, CCl₄, SiH₂Cl₂, Si₂Cl₆, CHCl₃, SO₂Cl₂, BCl₃, PCl₃, PCl₅, and POCl₃. In one example, the bromine-containing gas is at least one gas selected from the group consisting of Br₂, HBr, CBr₂F₂, C₂F₅Br, PBr₃, PBr₅, POBr₃, and BBr₃. In one example, the iodine-containing gas is at least one gas selected from the group consisting of HI, CF₃I, C₂F₅I, C₃F₇I, IF₅, IF₇, I₂, and PI₃. In one example, the gas containing a halogen other than fluorine may be at least one selected from the group consisting of a Cl₂ gas, a Br₂ gas, and an HBr gas. In one example, the gas containing a halogen other than fluorine is a Cl₂ gas or an HBr gas.

In one embodiment, the second processing gas may further include a boron-containing gas. The boron-containing gas is, for example, a BCl₃ gas.

In one embodiment, the second processing gas may further include an oxygen-containing gas. The oxygen-containing gas may be, for example, at least one gas selected from the group consisting of O₂, CO, CO₂, H₂O, and H₂O₂. In one example, the oxygen-containing gas may be an oxygen-containing gas other than H₂O, or specifically, at least one gas selected from the group consisting of O₂, CO, CO₂, and H₂O₂. The flow rate of the oxygen-containing gas may be adjusted based on the flow rate of another gas (e.g., a carbon-containing gas) included in the second processing gas.

In one embodiment, the second processing gas may further include a carbon-free fluorine-containing gas, such as an NF₃ gas, an SF₆ gas, a WF₆ gas, or an XeF₂ gas.

In one embodiment, the second processing gas may further include an inert gas. In one example, the inert gas may be a noble gas such as an Ar gas, a He gas, or a Kr gas, or an N₂ gas.

The second processing gas may include, in place of part or all of the HF gas, a gas that can generate an HF species in the plasma. The HF species includes at least any of a gas, radicals, or ions of HF. The gas that can generate an HF species may be, for example, a CF-based gas or a CHF-based gas described above. The gas that can generate an HF species may be a mixture gas including, for example, a hydrogen source and a fluorine source. The hydrogen source may be, for example, at least one selected from the group consisting of an H₂ gas, an NH₃ gas, an H₂O gas, an H₂O₂ gas, a CH₄ gas, and a C₃H₆ gas. The fluorine source may be a carbon-free fluorine-containing gas, such as an NF₃ gas, an SF₆ gas, a WF₆ gas, or an XeF₂ gas. The fluorine source may be a fluorine-containing gas containing carbon, such as a CF-based gas or a CHF-based gas.

In step ST13, a plasma is generated from the second processing gas in the chamber 10. For example, a source RF signal is provided to the lower electrode in the substrate support 11 or the upper electrode in the showerhead 13, or both. In response to an RF electric field being generated between the showerhead 13 and the substrate support 11, a plasma is generated from the etching gas in the chamber 10. An active species such as ions and radicals in the plasma etches the silicon-containing film SF exposed through the opening OP in the mask MK. A bias signal may be provided to the lower electrode in the substrate support 11 during plasma generation. In this case, a bias potential is generated between the plasma and the substrate W, drawing ions in the plasma toward the substrate W. This facilitates etching. The bias signal may be a bias DC signal provided from the first DC generator 32a or a bias RF signal provided from the second RF generator 31b. In one embodiment, no bias signal may be provided to the lower electrode in the substrate support 11.

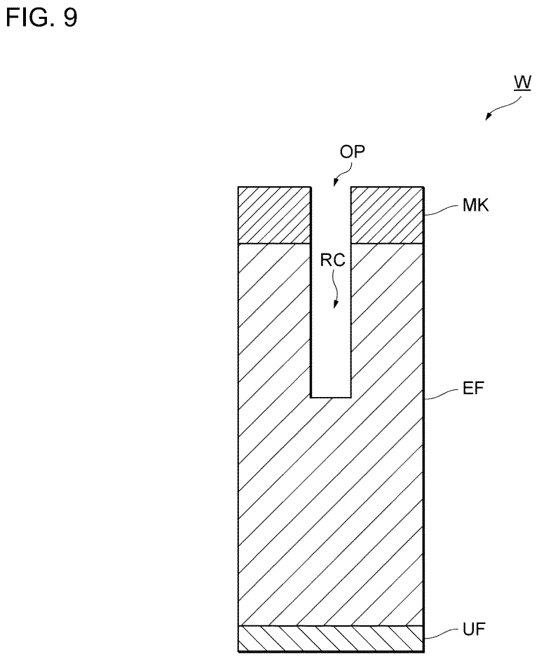

FIG. 9 is a diagram of the substrate W during the processing in step ST13, showing an example cross-sectional structure. As shown in FIG. 9, the active species in the plasma etches a portion of the silicon-containing film SF exposed through the opening OP in the depth direction (from the top to the bottom in FIG. 9). This forms a recess RC with a feature corresponding to the opening OP.

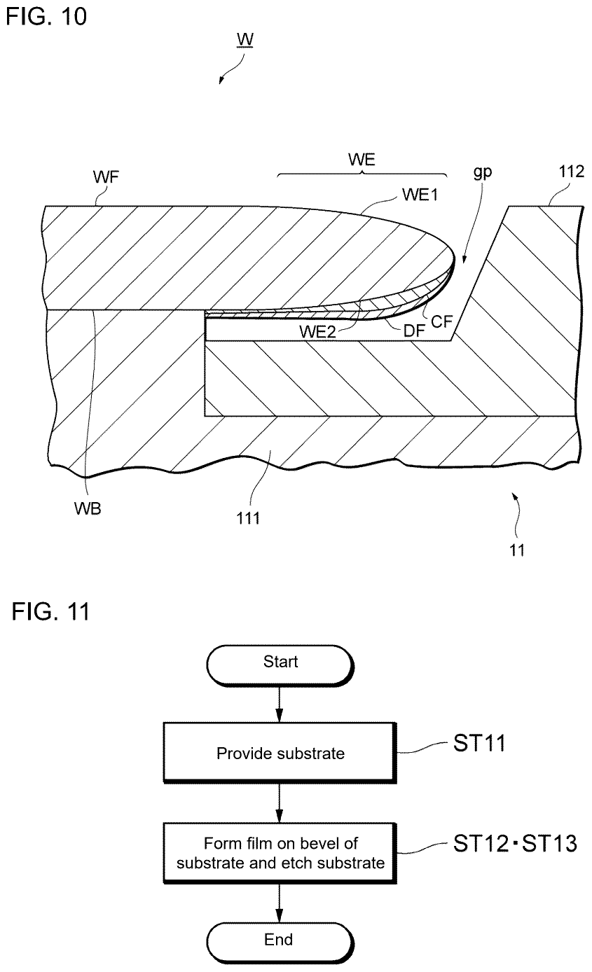

FIG. 10 is a diagram of an example bevel of the substrate W after the processing in step ST13. In step ST13, some of the particles generated in the plasma processing space 10s may reach the back surface WB through the clearance gp between the bevel WE of the substrate W and the ring assembly 112. Such particles may be, for example, particles in the plasma generated from the second processing gas or by-products resulting from etching. As shown in FIG. 10, the particles may adhere to the film CF on the end WE2 of the bevel WE, forming a deposition film DF. The deposition film DF may contain, for example, a hydrocarbon compound, a nitrogen compound, a phosphorus compound, a halogen compound, or a silicon compound.

The particles adhering to the film CF and forming the deposition film DF are less likely to separate from the substrate W than particles directly deposited on the silicon wafer (more specifically, particles deposited on an exposed silicon wafer without the film CF on the end WE2). This indicates that the film CF and the deposition film DF may have higher adhesion than the silicon wafer and the deposition film DF. For the first processing gas for forming the film CF being a CF-based gas, the film CF and the silicon wafer have higher adhesion between them. The film CF is thus less likely to separate from the substrate W. This may reduce particles generated in the chamber 10. This may also reduce arcing resulting from separation of a film from the substrate W.

The technique according to the above embodiment can reduce particles in the chamber.

### Modifications

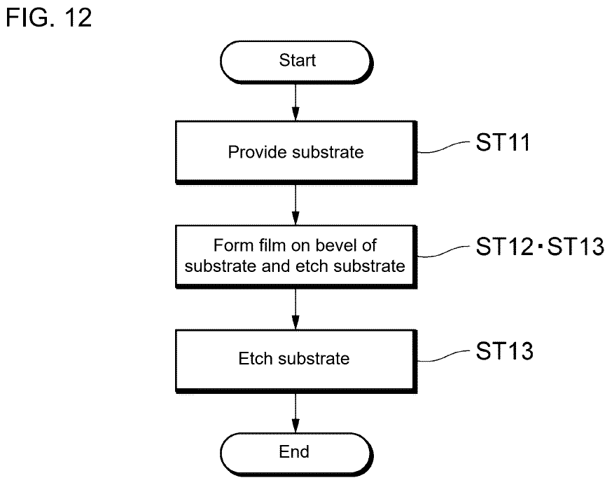

FIGS. 11 and 12 are flowcharts of other examples of the method MT. As shown in FIG. 11, for example, step ST12 and step ST13 may be performed simultaneously in the method MT. More specifically, a processing gas including the first processing gas and the second processing gas is supplied into the chamber 10 to generate a plasma from the processing gas. In this case, formation of the film CF on the bevel WE of the substrate W and etching of the silicon-containing film SF are performed in parallel. In this case, the flow rate of the first processing gas may be 5% or less, 3% or less, 1% or less, 0.7% or less, 0.5% or less, or 0.3% or less of the total flow rate of all components of the processing gas excluding any inert gas included in the processing gas.

For example, after step ST12 and step ST13 are performed simultaneously, step ST13 may further be performed for a given time T2 in the method MT as shown in FIG. 12. In one embodiment, a time (T1) for which step ST12 and step ST13 are performed simultaneously is shorter than the time (T2) for which step ST13 alone is further performed (T1<T2). In one embodiment, the time (T1) for which step ST12 and step ST13 are performed simultaneously may be 30% or less, 20% or less, or 10% or less of the total etching time (T1+T2).

### EXAMPLES

Examples of the processing method will now be described. One or more embodiments of the present disclosure are not limited to the examples described below.

### Example 1

In Example 1, a substrate with the same structure as the substrate shown in FIG. 6 was etched using the plasma processing apparatus 1 shown in FIGS. 2 and 3 and the procedure described with reference to FIG. 12. The first processing gas including a CF-based gas was used. The second processing gas including an HF gas, a phosphorus-containing gas, and a CHF-based gas was used. The first processing gas had a flow rate of about 0.5% of the total flow rate of the processing gas. The time for which step ST12 and step ST13 are performed simultaneously was about 10% of the total etching time.

### Comparative Example 1

In Comparative Example 1, the etching was performed under the same conditions as in Example 1 except that step ST12 was not performed.

In Example 1, no system error occurred in the plasma processing apparatus 1 until the etching ended. No film separation was observed on the bevel of the substrate W when the etching ended. In Comparative Example 1, the plasma processing apparatus 1 stopped due to a system error before the etching ended. In this state, film separations were observed at multiple positions on the bevel of the substrate W. These film separations may cause arcing in the chamber 10, possibly causing the system error.

The technique according to one exemplary embodiment of the present disclosure can reduce particles in a chamber.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and

### C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

The embodiments of the present disclosure further include the aspects described below.

### E1

A plasma processing apparatus, comprising:
a chamber;
a substrate support in the chamber;
a first gas guide unit configured to supply a first processing gas into the chamber;
a second gas guide unit configured to supply a second processing gas into the chamber; and
a controller configured to perform control operations including
   (a) providing, on the substrate support, a substrate including a silicon-containing film,
   (b) generating a plasma from the first processing gas supplied from the first gas guide unit into the chamber and forming a film on a bevel of the substrate, and
   (c) generating a plasma from the second processing gas supplied from the second gas guide unit into the chamber and etching the silicon-containing film.

### E2

The plasma processing apparatus according to E1, wherein
the first processing gas includes a CF-based gas.

### E3

The plasma processing apparatus according to E2, wherein
the CF-based gas includes at least one gas selected from the group consisting of a C₄F₈ gas, a C₄F₆ gas, a C₃F₈ gas, a C₃F₆ gas, and a CF₄ gas.

### E4

The plasma processing apparatus according to any one of E1 to E3, wherein
the second processing gas includes a CHF-based gas.

### E5

The plasma processing apparatus according to E4, wherein
the CHF-based gas includes at least one gas selected from the group consisting of a C₄H₂F₆ gas, a C₃H₂F₄ gas, and a CH₂F₂ gas.

### E6

The plasma processing apparatus according to any one of E1 to E4, wherein
the first gas guide unit is located radially outward from the second gas guide unit.

### E7

The plasma processing apparatus according to any one of E1 to E6, wherein
the first gas guide unit surrounds the second gas guide unit.

### E8

The plasma processing apparatus according to any one of E1 to E7, further comprising:
a showerhead facing the substrate support and including a plurality of gas supply holes over an area extending from a central portion to an outer peripheral portion of the showerhead,
wherein the first gas guide unit is located in the outer peripheral portion of the showerhead, and
the second gas guide unit is located in the central portion of the showerhead.

### E9

The plasma processing apparatus according to any one of E1 to E7, further comprising:
a showerhead facing the substrate support and including a plurality of gas supply holes, wherein
the first gas guide unit is located in a sidewall of the chamber, and
the second gas guide unit is located in the showerhead.

### E10

The plasma processing apparatus according to any one of E1 to E9, wherein
after (b) is performed, (c) is performed.

### E11

The plasma processing apparatus according to any one of E1 to E9, wherein
(b) and (c) are performed simultaneously.

### E12

The plasma processing apparatus according to any one of E1 to E9, wherein aft (b) and (c) are performed simultaneously, (c) is further performed.

### E13

The plasma processing apparatus according to any one of E1 to E12, wherein
the second processing gas further includes a hydrogen fluoride gas.

### E14

The plasma processing apparatus according to any one of aspects E1 to E13, wherein
the second processing gas further includes at least one gas selected from the group consisting of a phosphorus-containing gas, a gas containing a halogen other than fluorine, a metal-containing gas, an oxygen-containing gas, and an inert gas.

### E15

A plasma processing method, comprising:
(a) providing a substrate including a silicon-containing film on a substrate support in a chamber;
(b) generating a plasma from a first processing gas supplied from a first gas guide unit into the chamber and forming a film on a bevel of the substrate; and
(c) generating a plasma from a second processing gas supplied from a second gas guide unit into the chamber and etching the silicon-containing film.

### E16

The plasma processing method according to E15, wherein
the first processing gas includes a CF-based gas.

### E17

The plasma processing method according to E15 or E16, wherein
the second processing gas includes a CHF-based gas.

### E18

The plasma processing method according to any one of E15 to E17, wherein
after (b) is performed, (c) is performed.

### E19

The plasma processing method according to any one of E15 to E17, wherein (b) and (c) are performed simultaneously.

### E20

The plasma processing method according to any one of E15 to E17, wherein after (b) and (c) are performed simultaneously, (c) is further performed.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

What is claimed is:

1. A plasma processing apparatus, comprising:
a chamber;
a substrate support in the chamber;
a first gas guide structure to supply a first processing gas into the chamber;
a second gas guide structure to supply a second processing gas into the chamber; and
controller circuitry configured to perform control operations including
(a) providing, on the substrate support, a substrate including a silicon-containing layer,
(b) generating a plasma from the first processing gas supplied from the first gas guide structure into the chamber and forming a layer on a bevel of the substrate, and
(c) generating a plasma from the second processing gas supplied from the second gas guide structure into the chamber and etching the silicon-containing layer.

2. The plasma processing apparatus according to claim 1, wherein
the first processing gas includes a CF-based gas.

3. The plasma processing apparatus according to claim 2, wherein
the CF-based gas includes at least one gas selected from the group consisting of a C₄F₈ gas, a C₄F₆ gas, a C₃F₈ gas, a C₃F₆ gas, and a CF₄ gas.

4. The plasma processing apparatus according to claim 2, wherein
the second processing gas includes a CHF-based gas.

5. The plasma processing apparatus according to claim 4, wherein
the CHF-based gas includes at least one gas selected from the group consisting of a C₄H₂F₆ gas, a C₃H₂F₄ gas, and a CH₂F₂ gas.

6. The plasma processing apparatus according to claim 1, wherein
the first gas guide structure is located radially outward from the second gas guide structure.

7. The plasma processing apparatus according to claim 6, wherein
the first gas guide structure surrounds the second gas guide structure.

8. The plasma processing apparatus according to claim 1, further comprising:
a showerhead facing the substrate support and including a plurality of gas supply holes over an area extending from a central portion to an outer peripheral portion of the showerhead,
wherein the first gas guide structure is located in the outer peripheral portion of the showerhead, and
the second gas guide structure is located in the central portion of the showerhead.

9. The plasma processing apparatus according to claim 1, further comprising:
a showerhead facing the substrate support and including a plurality of gas supply holes,
wherein the first gas guide structure is located in a sidewall of the chamber, and
the second gas guide structure is located in the showerhead.

10. The plasma processing apparatus according to claim 1, wherein
after (b) is performed, (c) is performed.

11. The plasma processing apparatus according to claim 1, wherein
(b) and (c) are performed simultaneously.

12. The plasma processing apparatus according to claim 11, wherein
after (b) and (c) are performed simultaneously, (c) is further performed.

13. The plasma processing apparatus according to claim 1, wherein
the second processing gas further includes a hydrogen fluoride gas.

14. The plasma processing apparatus according to claim 13, wherein
the second processing gas further includes at least one gas selected from the group consisting of a phosphorus-containing gas, a gas containing a halogen other than fluorine, a metal-containing gas, an oxygen-containing gas, and an inert gas.

15. A plasma processing method, comprising:
(a) providing a substrate including a silicon-containing layer on a substrate support in a chamber;
(b) generating a plasma from a first processing gas supplied from a first gas guide structure into the chamber and forming a layer on a bevel of the substrate; and
(c) generating a plasma from a second processing gas supplied from a second gas guide structure into the chamber and etching the silicon-containing layer.

16. The plasma processing method according to claim 15, wherein
the first processing gas includes a CF-based gas.

17. The plasma processing method according to claim 16, wherein
the second processing gas includes a CHF-based gas.

18. The plasma processing method according to claim 16, wherein
after (b) is performed, (c) is performed.

19. The plasma processing method according to claim 17, wherein
(b) and (c) are performed simultaneously.

20. The plasma processing method according to claim 17, wherein
after (b) and (c) are performed simultaneously, (c) is further performed.
